(19) United States
(12) Patent Application Publication
(10) Pub. No.: US 2008/0164598 A1
(43) Pub. Date: Jul. 10, 2008

(54) Semiconductor module

(76) Inventor: Horst Theuss, Wenzenbach (DE)

Correspondence Address: BRINKS HOFER GILSON & LIONE/INFINEON;INFINEON, PO BOX 10395, CHICAGO, IL, 60610, US

(21) Appl. No.: 11/650,650

(22) Filed: Jan. 8, 2007

(51) Int. Cl. H01L 23/48; H01L 21/00

(52) U.S. Cl. 257/690; 438/110; 257/E23.01; 257/E21.001

(57) ABSTRACT

A module includes a semiconductor chip, which has at least one movable element, a first substrate of a glass material or semiconductor material, which covers a first main surface of the semiconductor chip, and a second substrate of a glass material or semiconductor material, which covers a second main surface of the semiconductor chip. Part at least of the semiconductor chip or of the first substrate or of the second substrate lies open.

In the development of packages for semiconductor chips which contain movable elements, special requirements have to be taken into account. For example, movable elements react sensitively to mechanical stresses that may occur during package fabrication or that may be caused by specific properties of the packages.

Against this background, a module as claimed in independent claims 1, 15 and 26 and a method as claimed in independent claims 11, 21 and 31 are provided. Advantageous developments and refinements are provided in the subclaims.

According to one refinement, a module comprises a semiconductor chip with a least one movable element, a first substrate and a second substrate. The two substrates are produced from a glass material or semiconductor material. The first substrate covers a first main surface of the semiconductor chip, and the second substrate covers a second main surface of the semiconductor chip. Part at least of the semiconductor chip or of the first substrate or of the second substrate lies open.

According to a further refinement, a module comprises a semiconductor chip with a least one movable element, a first substrate and a second substrate. The two substrates respectively have a coefficient of thermal expansion in the range from 0.3·10⁻⁶/K to 8.2·10⁻⁶/K. The first substrate covers a first main surface of the semiconductor chip, and the second substrate covers a second main surface of the semiconductor chip. Part at least of the semiconductor chip or of the first substrate or of the second substrate lies open.

According to a further refinement, a module comprises a semiconductor chip with a least one movable element, a first substrate and a second substrate. The first substrate covers a first main surface of the semiconductor chip. The second substrate covers a second main surface of the semiconductor chip and has a recess facing the at least one movable element. Part at least of the semiconductor chip or of the first substrate or of the second substrate lies open.

According to a further refinement, a semiconductor substrate which has a least two movable elements is provided. A first substrate is applied to a first main surface of the semiconductor substrate. After the application of the first substrate to the first main surface of the semiconductor substrate, the semiconductor substrate is separated into a least two semiconductor modules, each with at least one movable element.

The invention is explained in more detail below by way of example with reference to the drawings, in which:

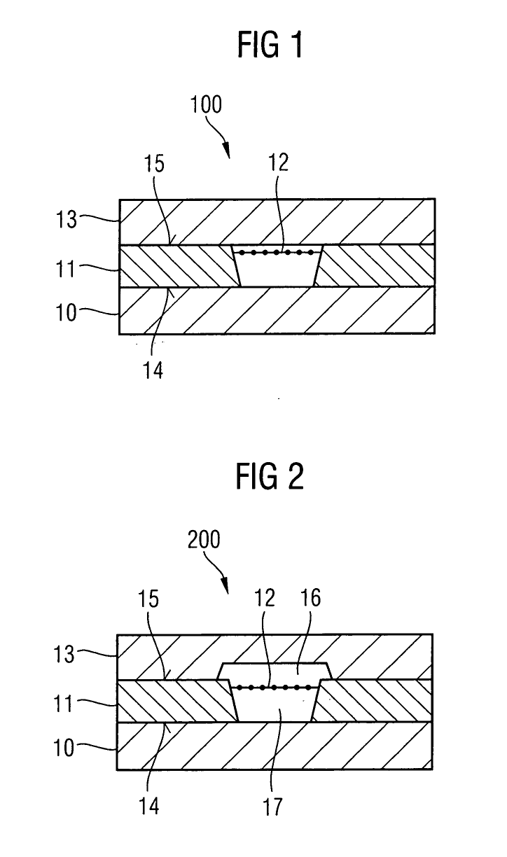

FIG. 1 shows a schematic representation of a module 100 as an exemplary embodiment;

FIG. 2 shows a schematic representation of a module 200 as a further exemplary embodiment;

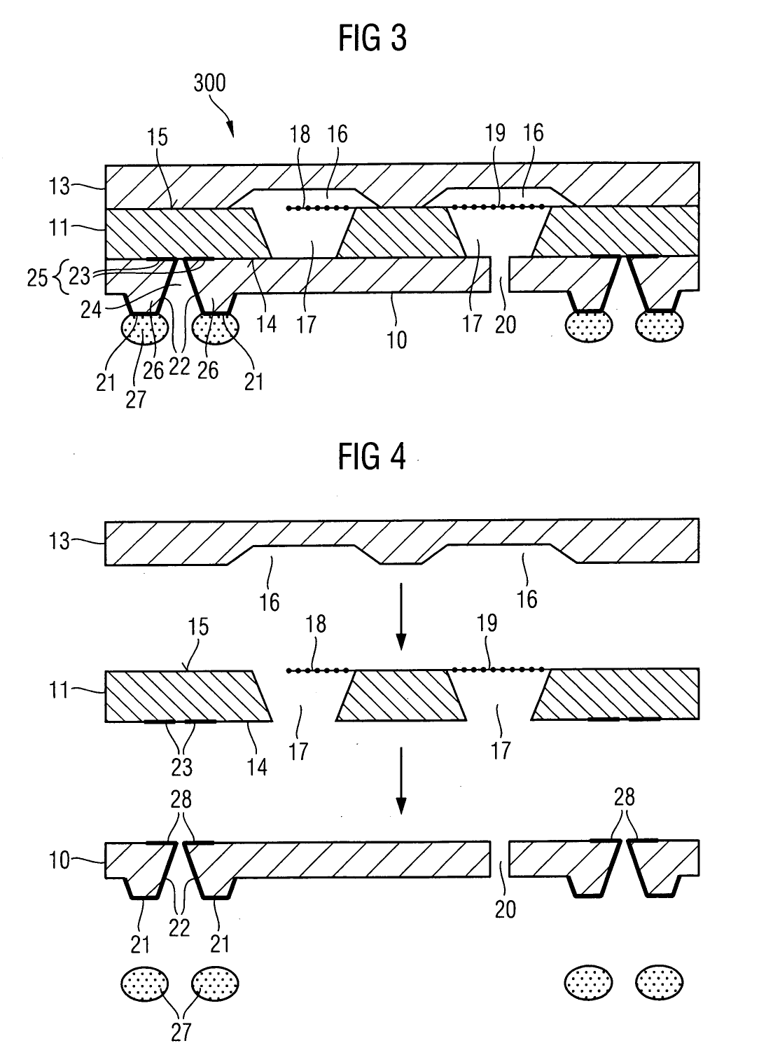

FIG. 3 shows a schematic representation of a module 300 as a further exemplary embodiment;

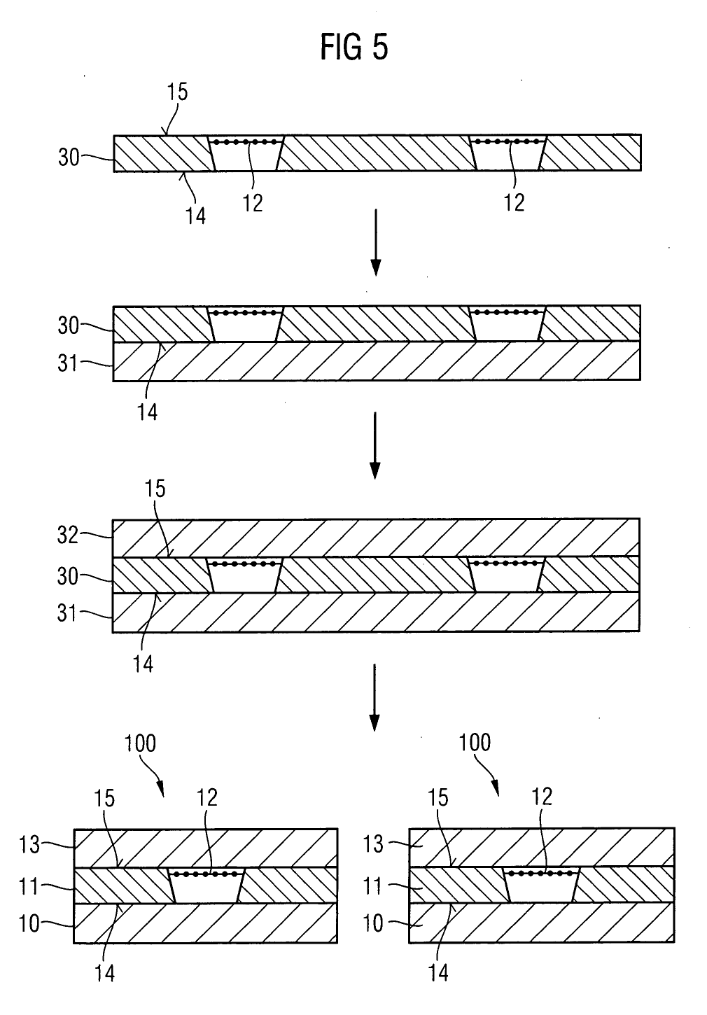

FIG. 4 shows a schematic representation of a method for producing the module 300 as a further exemplary embodiment; and

FIG. 5 shows a schematic representation of a method for producing the module 100 as a further exemplary embodiment.

There follows a description of modules which comprise semiconductor chips with movable elements and methods for producing the modules. The invention is independent of the type of semiconductor chip and movable elements. The movable elements may for example be mechanical elements, sensors and actuators and may for example be designed as pressure sensors, acceleration sensors, rotation sensors or microphones. The semiconductor chips in which the movable elements are embedded comprise electronic circuits, which for example activate the movable elements or further process signals that are produced by the movable elements. In the same way as the semiconductor chips, the movable elements may be produced from semiconductor materials, and also from other materials, such as for example plastics. In the literature, combinations of mechanical elements, sensors and actuators with electronic circuits in a semiconductor chip are often referred to as an MEMS (Micro-Electro-Mechanical System).

In FIG. 1, a module 100 is represented in cross section as an exemplary embodiment. The module 100 comprises a substrate 10, a semiconductor chip 11, arranged on the substrate 10 and having a movable element 12, and a substrate 13 arranged on the semiconductor chip 11. The substrates 10 and 13 form at least part of a package of the semiconductor chip 11. The substrates 10 and 13 and the semiconductor chip 11 are stacked one on top of the other in such a way that the two main surfaces 14 and 15 of the semiconductor chip 11 are respectively covered by one of the substrates 10 and 13. The substrates 10 and 13 serve the purpose of protecting the semiconductor chip 11 and the movable element 12 from environmental influences, such as for example dirt, wetness or mechanical impact. Part of the semiconductor chip 11 and/or of the substrate 10 and/or of the substrate 13 lies open. This may for example be an edge surface of the semiconductor chip 11, of the substrate 10 or of the substrate 13.

The movable element 12 may for example be a membrane, a bridge structure or a tongue structure and be used for example as a sensor or actuator. Together with the movable element 12, the semiconductor chip 11 may for example form an MEMS and be designed as a pressure sensor, acceleration sensor, rotation sensor or microphone.

The two substrates 10 and 13 may be produced for example from a glass material or semiconductor material. The use of glass or semiconductor materials for the substrates 10 and 13 is accompanied by several advantages. A first advantage of this measure is that stress-free mounting of the semiconductor chip 11 between the substrates 10 and 13 is made possible. It is not necessary to encapsulate the semiconductor chip 11 with a casting compound, for example a plastics material or glob top or other polymer-containing casting materials, during package fabrication. The encapsulation with a casting compound often causes mechanical stresses in the semiconductor chip 11 and in particular in the movable element 12, as a result of which their functional capability may be restricted. Furthermore, when encapsulating with a casting compound there is the risk of the movable element 12 coming directly into contact with the casting compound. Even if the movable element 12 is only wetted with the casting compound, this would lead to functional failure.

A further advantage that accompanies the use of glass or semiconductor materials for the substrates 10 and 13 is attributable to the fact that the substrates 10 and 13 forming the package of the semiconductor chip 11 have the same or at least similar thermomechanical properties as the semiconductor chip 11, which consists for example predominantly of silicon. When there are temperature changes, the semiconductor chip 11 and the substrates 10 and 13 therefore behave identically, or at least similarly, for example with regard to their expansion. As a result, stress-free mounting of the semiconductor chip 11 in the package surrounding it is ensured. Such stress-free mounting is advantageous in particular for the functional capability of the movable element 12, since many movable elements 12 that are used in MEMSs react very sensitively to mechanical stresses.

Silicon comes into consideration for example as the semiconductor material for the substrates 10 and 13. If the semiconductor chip 11 has also been produced on a silicon basis, the thermomechanical properties, for example the coefficient of thermal expansion, of the semiconductor chip 11 and of the substrates 10 and 13 are very similar. However, other semiconductor and glass materials may also be used for the production of the substrates 10 and 13, since the thermomechanical behavior of these materials is very similar to that of the semiconductor chip 11.

As an alternative to glass or semiconductor materials, other materials may be used for the production of the two substrates 10 and 13, provided that the coefficient of thermal expansion of these materials substantially corresponds to the coefficient of thermal expansion of the semiconductor material from which the semiconductor chip 11 was fabricated. The coefficient of thermal expansion determines how a material expands when there is a change in temperature. Adequate adaptation of the thermomechanical behavior of the substrates 10 and 13 forming the package to the thermomechanical behavior of the semiconductor chip 11 is ensured if the substrates 10 and 13 have a coefficient of thermal expansion in the range from 0.3·10⁻⁶/K to 8.2·10⁻⁶/K. In particular, the substrates 10 and 13 may have a coefficient of thermal expansion in the range from 4.0·10⁻⁶/K to 4.5·10⁻⁶/K. Furthermore, a material which has approximately the same coefficient of thermal expansion as silicon, of about 4.2·10⁻⁶/K, may be chosen for example for the substrates 10 and 13. The use of substrates 10 and 13 with the stated coefficients of expansion has the effect of minimizing mechanical stresses in the movable element 12 to the greatest extent.

To produce the module 100, the semiconductor chip 11 is provided and the substrates 10 and 13 are applied to the main surfaces 14 and 15 of the semiconductor chip 11. After applying the two substrates 10 and 13 to the main surfaces 14 and 15 of the semiconductor chip 11, part at least of the semiconductor chip 11 or of the substrate 10 or of the substrate 13 lies open.

In FIG. 2, a module 200 is represented in cross section as a further exemplary embodiment. The structure of the module 200 is similar to the structure of the module 100. The module 200 comprises a substrate 10, a semiconductor chip 11, arranged on the substrate and having a movable element 12, and a substrate 13 arranged on the semiconductor chip 11. The substrates 10 and 13 form at least part of a package of the semiconductor chip 11. The substrate 13 has a recess 16 facing the movable element 12. In the assembled state of the module 200, the recess 16 forms a cavity, which may be required for the mobility and/or functional capability of the movable element 12. Part of the semiconductor chip 11 and/or of the substrate 10 and/or of the substrate 13 lies open. This may for example be an edge surface of the semiconductor chip 11, of the substrate 10 or of the substrate 13.

The movable element 12 may be formed for example as a membrane, and the cavity formed by the recess 16 forms a back volume of the membrane 12. A back volume is an enclosed air space which, with every deflection of the membrane 12, brings about a restoring force in addition to the restoring force that is caused by the elastic properties of the membrane 12.

The semiconductor chip 11 may, furthermore, have a recess 17, in which the movable element 12 is arranged or which is delimited by the movable element 12. The recess 17, which in the assembled state of the module 200 may form a cavity, may also be required for the mobility and/or functional capability of the movable element 12.

The recesses 16 and 17 may be introduced into the substrate 13 and the semiconductor chip 11, respectively, for example by etching steps, but also by mechanical working operations, such as for example milling or drilling.

The movable element 12 of the module 200 may be designed in the same way as the movable element 12 of the module 100 that is described above. The substrates 10 and 13 of the module 200 may be produced from a glass material or semiconductor material or from a material with a coefficient of thermal expansion in the range from 0.3·10⁻⁶/K to 8.2·10⁻⁶/K, and in particular in the range from 4.0·10⁻⁶/K to 4.5·10⁻⁶/K, but may also be produced from different materials.

To produce the module 200, the semiconductor chip 11 is provided and the substrates 10 and 13 are applied to the main surfaces 14 and 15 of the semiconductor chip 11. In this case, the substrate 13 is applied to the semiconductor chip 11 with the side that has the recess 16. After applying the two substrates 10 and 13 to the main surfaces 14 and 15 of the semiconductor chip 11, part at least of the semiconductor chip 11 or of the substrate 10 or of the substrate 13 lies open.

In FIG. 3, a module 300, which represents a development both of the module 100 and of the module 200, is represented. In the case of the module 300, the substrates 10 and 13 are produced from a glass material or semiconductor material or from a material with a coefficient of thermal expansion in the range from 0.3·10⁻⁶/K to 8.2·10⁻⁶/K, and in particular in the range from 4.0·10⁻⁶/K to 4.5·10⁻⁶/K. The semiconductor chip 11 of the module 300 contains as movable elements a tongue structure 18 and a membrane structure 19. The tongue structure 18 and the membrane structure 19 are arranged in cavities which are formed by the recesses 16 and 17. The substrate 10 has an opening 20, which leads to the recess 17 adjacent the membrane structure 19. Together with the circuits integrated in the semiconductor chip 11, the tongue structure 18 is formed for example as an acceleration sensor and the membrane structure 19 is formed for example as a pressure sensor. In this case, the opening 20 ensures that the air pressure in the cavity formed by the recess 17 corresponds to the air pressure outside the module 300.

In FIG. 3, the substrate 10 is provided on its underside with external contact elements 21, which are electrically connected by means of connecting lines 22 to contact areas 23 of the semiconductor chip 11. The semiconductor chip 11 can be electrically contacted from the outside by means of the external contact elements 21. In FIG. 3, the connecting lines 22 lead through passages 24 in the substrate and are designed as what are known as via (Vertical Interconnect Access) connections. Alternatively, the connecting lines 22 may lead from the external contact elements 21 of the substrate 10 along the surface and over an edge region 25 of the substrate 10 to the contact areas 23 of the semiconductor chip 11.

The connecting lines 22 may be created on the substrate 10 by means of customary wafer processes. For example, metal layers are sputtered onto the substrate 10 and subsequently structured photolithographically. If thicker layers are required, the applied metal layers may be galvanically reinforced (what is known as electroplating). It may also be provided that both sides of the substrate 10 are coated. In this case, the substrate 10 has metallic coatings which are facing the semiconductor chip 11 and ensure reliable electrical contacting with the semiconductor chip 11. Such coatings 28 are represented by way of example in FIG. 4.

The external contact elements 21 and the connecting lines 22 may be produced from a metal, such as for example aluminum, gold or copper, or an alloy. The contact areas 23 of the semiconductor chip 11 may be coated with a metallization layer, for example of aluminum, gold, copper or an alloy.

As is shown in FIG. 3, the substrate 10 may have elevations 26 in the region of the contact elements 21. When the module 300 is mounted on a printed circuit board, the elevations 26 facilitate the contacting of the external contact elements 21 with the corresponding contact elements of the printed circuit board. In addition, solder deposits or solder balls 27, which serve for the soldering of the module 300 to the contact elements of a printed circuit board, may have been applied to the external contact elements 21.

On account of the thermomechanical properties of the substrates 10 and 13, the mechanical stresses occurring during the mounting of the module 300 on a printed circuit board are absorbed by the substrates 10 and 13, so that the mounting involves particularly low stress for the semiconductor chip 11 and in particular the tongue structure 18 or the membrane structure 19. Particularly good results are achieved if the printed circuit board onto which the module 300 is mounted is also adapted in its thermomechanical properties to the material that is used for the substrates 10 and 13. This is the case for example for a printed circuit board fabricated from a ceramic.

The active main surface of the semiconductor chip 11 on which electrically operable structures or circuits are located may be one of the two main surfaces 14 and 15. Consequently, the semiconductor chip 11 may be aligned both in such a way that its active main surface is facing the substrate 10 and in such a way that the active main surface is adjacent the substrate 13. If the main surface 15 is the active main surface of the semiconductor chip 11, connecting lines must be provided from the contact areas of the active main surface to the contact areas 23. For this purpose, plated-through holes (via connections) may lead through vertical passages in the semiconductor chip 11.

The active main surface of the semiconductor chip 11 may be provided with a wiring layer, in which interconnects are led from contact areas of the semiconductor chip 11 to the contact areas 23.

In FIG. 4, a method for producing the module 300 is schematically represented as a further exemplary embodiment. In the method, as shown in FIG. 4, the substrate 10, the semiconductor chip 11 and the substrate 13 are stacked one on top of the other. During the stacking, both the substrates 10 and 13 and the semiconductor chip 11 are preferably still part of a respective wafer. Consequently, it is not already singulated substrates 10 and 13 and a singulated semiconductor chip 11 that are stacked one on top of the other to produce the module 300 but instead three wafers, or at least parts of three wafers, which contain the structures shown in FIG. 4, that are stacked one on top of the other. The stacking at wafer level permits low-cost production, which is compatible with what is known as “wafer-level packaging”.

The wafers may be connected to one another for example by soldering, adhesive bonding, anodic bonding or glass-frit bonding. In the case of anodic bonding, an electric field is applied to the stack formed by the wafers that are stacked one on top of the other. The current through the wafer stack that is induced as a result leads to fusing of the wafers in the contact regions. In the case of glass-frit bonding, a glass solder or glass powder is introduced between the wafers. Subsequently, the wafer stack is heated to the melting point of the glass solder or glass powder, whereby a solid connection between the wafers is obtained.

The modules 300 are subsequently singulated, for example by sawing.

The external contact elements 21 and the connecting lines 22 may be applied to the substrate 10 either before the stacking of the wafers or thereafter.

In FIG. 5, a method for producing the module 100 is represented as a further exemplary embodiment. For this purpose, a semiconductor substrate 30, which contains at least two movable elements 12, for example two open-lying membranes, is provided. The semiconductor substrate 30 may for example be a semiconductor wafer which contains at least two semiconductor chips. A substrate 31 is applied to a main surface 14 of the semiconductor substrate 30. Furthermore, a substrate 32 may be applied to a main surface 15 of the semiconductor substrate 30. After applying the substrate 31 to the main surface 14 of the semiconductor substrate 30, and in particular after applying the substrate 32 to the main surface 15 of the semiconductor substrate 30, the semiconductor substrate 30 is separated into at least two modules 100, each with at least one movable element 12.

After the separating of the semiconductor substrate 30, for example by sawing, edge regions for example of the modules 100 lie open.

The modules 200 and 300 can also be produced for example by the method shown in FIG. 5.

The substrates 31 and 32 may be connected to the semiconductor substrate 30 for example by soldering, adhesive bonding, anodic bonding or glass-frit bonding.

The substrates 31 and 32 may be produced from a glass material or semiconductor material or from a material with a coefficient of thermal expansion in the range from 0.3·10⁻⁶/K to 8.2·10⁻⁶/K, and in particular in the range from 4.0·10⁻⁶/K to 4.5·10⁻⁶/K.

The substrate 31 or 32 may have one or more recesses that face the movable elements 12 and may be designed in a way similar to the recesses 16 of the modules 200 and 300.

1. A module comprising:
a semiconductor chip, which has at least one movable element;
a first substrate of a glass material or semiconductor material, which covers a first main surface of the semiconductor chip; and
a second substrate of a glass material or semiconductor material, which covers a second main surface of the semiconductor chip,
wherein at least part of the semiconductor chip or of the first substrate or of the second substrate lying open.

2. The module as claimed in claim 1, the first substrate and/or the second substrate having at least one recess facing the at least one movable element.

3. The module as claimed in claim 1, connecting lines having been applied to the first substrate.

4. The module as claimed in claim 3, at least one of the connecting lines leading through a passage in the first substrate and/or at least one of the connecting lines leading over a lateral surface region of the first substrate.

5. The module as claimed in claim 1, external contact elements having been applied to the first substrate.

6. The module as claimed in claim 5, the external contact elements having been applied to elevations of the first substrate.

7. The module as claimed in claim 5, solder deposits having been applied to the external contact elements.

8. The module as claimed in claim 1, the first substrate and/or the second substrate having at least one passage, which leads to the at least one movable element.

9. The module as claimed in claim 1, wherein connections between the two substrates and the semiconductor chip having been respectively established by adhesive bonding and/or soldering and/or application of an electric field and/or melting of a glass material or semiconductor material.

10. The module as claimed in claim 1, wherein the semiconductor chip with the at least one movable element being designed as a pressure sensor and/or acceleration sensor and/or rotation sensor and/or microphone.

11. A method, comprising:
providing a semiconductor substrate, the semiconductor substrate having at least two movable elements;
applying a first substrate of a glass material or semiconductor material to a first main surface of the semiconductor substrate; and
separating after the application of the first substrate to the first main surface of the semiconductor substrate, the semiconductor substrate into at least two semiconductor modules, each of the at least two semiconductor modules having at least one movable element.

12. The method as claimed in claim 11, the semiconductor substrate being a semiconductor wafer.

13. The method as claimed in claim 11, further comprising the step of applying a second substrate of a glass material or semiconductor material to a second main surface of the semiconductor substrate.

14. The method as claimed in claim 13, further comprising the step of separating the semiconductor substrate into at least two semiconductor modules, each of the at least two semiconductor modules having at least one movable element, after the application of the second substrate to the second main surface of the semiconductor substrate.

15. A module comprising:
a semiconductor chip, which has at least one movable element;
a first substrate, which covers a first main surface of the semiconductor chip and has a coefficient of thermal expansion in the range from 0.3·10⁻⁶/K to 8.2·10⁻⁶/K; and
a second substrate, which covers a second main surface of the semiconductor chip and has a coefficient of thermal expansion in the range from 0.3·10⁻⁶/K to 8.2·10⁻⁶/K,
at least part of the semiconductor chip or of the first substrate or of the second substrate lying open.

16. The module as claimed in claim 15, the first substrate and/or the second substrate having at least one recess facing the at least one movable element.

17. The module as claimed in claim 15, connecting lines having been applied to the first substrate.

18. The module as claimed in claim 17, at least one of the connecting lines leading through a passage in the first substrate and/or at least one of the connecting lines leading over a lateral surface region the first substrate.

19. The module as claimed in claim 15, external contact elements having been applied to the first substrate.

20. The module as claimed in one of claim 15, the first substrate and the second substrate having a coefficient of thermal expansion in the range from 4.0·10⁻⁶/K to 4.5·10⁻⁶/K.

21. A method, comprising:
providing a semiconductor substrate, the semiconductor substrate having at least two movable elements;
applying a first substrate, which has a coefficient of thermal expansion in the range from 0.3·10⁻⁶/K to 8.2·10⁻⁶/K, to a first main surface of the semiconductor substrate; and
separating after the application of the first substrate to the first main surface of the semiconductor substrate, the semiconductor substrate into at least two semiconductor modules, each of the at least two semiconductor modules having at least one movable element.

22. The method as claimed in claim 21, the semiconductor substrate being a semiconductor wafer.

23. The method as claimed in claim 21, further comprising the step of applying a second substrate, which has a coefficient of thermal expansion in the range from 0.3·10⁻⁶/K to 8.2·10⁻⁶/K, to a second main surface of the semiconductor substrate.

24. The method as claimed in claim 23, further comprising the step of separating the semiconductor substrate into at least two semiconductor modules, each of the at least two semiconductor modules having at least one movable element, after the application of the second substrate to the second main surface of the semiconductor substrate.

25. The method as claimed in claim 21, the first substrate and/or the second substrate having a coefficient of thermal expansion in the range from 4.0·10^{31 6}/K to 4.5·10⁻⁶/K.

26. A module comprising:
a semiconductor chip, which has at least one movable element;
a first substrate, which covers a first main surface of the semiconductor chip; and
a second substrate, which covers a second main surface of the semiconductor chip and has at least one recess facing the at least one movable element,
at least part of the semiconductor chip or of the first substrate or of the second substrate lying open.

27. The module as claimed in claim 26, the at least one recess being produced by an etching step.

28. The module as claimed in claim 26, connecting lines having been applied to the first substrate.

29. The module as claimed in claim 28, at least one of the connecting lines leading through a passage in the first substrate and/or at least one of the connecting lines leading over a lateral surface region of the first substrate.

30. The module as claimed in claim 26, external contact elements having been applied to the first substrate.

31. A method, comprising:
providing a semiconductor substrate having at least two movable elements;
applying a first substrate to a first main surface of the semiconductor substrate;
applying a second substrate with a side which has at least one recess to a second main surface of the semiconductor substrate; and
separating after the application of the first substrate and of the second substrate to the main surfaces of the semiconductor substrate, the semiconductor substrate into at least two semiconductor modules, each of the at least two semiconductor modules having at least one movable element.

32. The method as claimed in claim 31, the semiconductor substrate being a semiconductor wafer.
